(19) United States
(12) Patent Application Publication
(10) Pub. No.: US 2022/0022316 A1
(43) Pub. Date: Jan. 20, 2022

(54) PACKAGE CARRIER AND MANUFACTURING METHOD THEREOF

(71) Applicant: Unimicron Technology Corp., Taoyuan City (TW)

(72) Inventors: Po-Wei Chen, New Taipei City (TW); Wei-Ti Lin, Hsinchu County (TW); Chun-Hsien Chien, Hsinchu City (TW)

(73) Assignee: Unimicron Technology Corp., Taoyuan City (TW)

(21) Appl. No.: 16/996,911

(22) Filed: Aug. 19, 2020

(30) Foreign Application Priority Data
Jul. 15, 2020 (TW) 109123873

(51) Int. Cl. H05K 1/11; H05K 3/10; H05K 3/46; H05K 3/18; H01L 23/498

(52) U.S. Cl. CPC H05K 1/111; H05K 3/107; H05K 3/4661; H05K 2201/0939; H01L 23/49816; H01L 23/49822; H01L 23/49838; H05K 3/184

(57) ABSTRACT

A package carrier includes a build-up circuit structure, a first insulation protective layer, a plurality of connection pads, and a plurality of metal balls. The build-up circuit structure has an upper surface. The first insulation protective layer is disposed on the upper surface of the build-up circuit structure and has a plurality of first openings. The connection pads are respectively disposed in the first openings of the first insulation protective layer and are structurally and electrically connected to the build-up circuit structure. Each of the connection pads has an arc-shaped groove. The metal balls are respectively disposed in the arc-shaped groove of the connection pads. The metal balls and the corresponding connection pads define a plurality of bump structures, and a plurality of top surfaces of the bump structures are on a same plane.

### CROSS-REFERENCE TO RELATED APPLICATION

This application claims the priority benefit of Taiwan application serial no. 109123873, filed on Jul. 15, 2020. The entirety of the above-mentioned patent application is hereby incorporated by reference herein and made a part of this specification.

### BACKGROUND OF THE INVENTION

### 1. Field of the Invention

The invention relates to a substrate structure and a manufacturing method thereof, and in particular, to a package carrier and a manufacturing method thereof.

### 2. Description of Related Art

In order to achieve a chip stacking structure, a flip chip or package-on-package (POP) circuit substrate or carrier is provided with an electroplated copper pillar structure. However, due to the necessary electroplating and build-up processes during manufacturing of the circuit board or the carrier, the coplanarity is not good, which conversely affects a height of the electroplated copper pillar structure. In other words, the surface coplanarity of the circuit substrate or the carrier with the copper pillar structure is not good. In order to solve the above-mentioned problems, before the chip is packaged on the circuit substrate or the carrier with the copper pillar structure, the copper pillar structure needs to be additionally subjected to a grinding process to improve the chip packaging yield. However, due to the need for the additional grinding process, the manufacturing process is redundant and the manufacturing cost is high.

### SUMMARY OF THE INVENTION

The invention provides a package carrier, which has better flatness.

The invention provides a method for manufacturing a package carrier, which is used to manufacture the above-mentioned package carrier, thereby improving the chip packaging yield.

The package carrier of the invention includes a build-up circuit structure, a first insulation protective layer, a plurality of connection pads, and a plurality of metal balls. The build-up circuit structure has an upper surface. The first insulation protective layer is disposed on the upper surface of the build-up circuit structure and has a plurality of first openings. The connection pads are respectively disposed in the first openings of the first insulation protective layer and are structurally and electrically connected to the build-up circuit structure. Each of the connection pads has an arc-shaped groove. The metal balls are respectively disposed in the arc-shaped grooves of the connection pads. The metal balls and the corresponding connection pads respectively define a plurality of bump structures, and a plurality of top surfaces of the bump structures are on a same plane.

In an embodiment of the invention, the package carrier further includes a second insulation protective layer disposed on a lower surface of the build-up circuit structure relative to the upper surface and having a plurality of second openings, where the second openings expose a portion of the build-up circuit structure.

In an embodiment of the invention, the build-up circuit structure includes at least one dielectric layer, at least one circuit layer, and at least one conductive via. The dielectric layer covers the connection pad, the circuit layer is disposed on the dielectric layer, and the conductive via penetrates the dielectric layer to electrically connect at least one of the connection pads and the at least one circuit layer.

In an embodiment of the invention, each of the metal balls includes a copper core, a first metal layer, and a second metal layer. The first metal layer covers a surface of the copper core, and the second metal layer covers the first metal layer.

In an embodiment of the invention, the second metal layer completely covers the first metal layer, and the metal balls and the corresponding connection pads respectively define a plurality of flat bump structures.

In an embodiment of the invention, the second metal layer covers a portion of the first metal layer, and the metal balls and the corresponding connection pads respectively define a plurality of top-convex bump structures.

The method for manufacturing a package carrier of the invention includes the following steps. A substrate including a core layer, two first copper foil layers, and two second copper foil layers is provided, where the two first copper foil layers are disposed on two opposite surfaces of the core layer and are located between the core layer and the two second copper foil layers. Two photoresist layers are respectively formed on the two second copper foil layers of the substrate, where the two photoresist layers have a plurality of openings respectively, and the openings expose a portion of the two second copper foil layers. A plurality of metal balls is bonded to the two second copper foil layers exposed by the openings. Two first insulation protective layers are respectively formed on the two photoresist layers, where the two first insulation protective layers have a plurality of first openings respectively, and the first openings respectively expose the metal balls. A plurality of connection pads is formed in the first openings of the two first insulation protective layers and extending onto the two first insulation protective layers, where the connection pads respectively cover the metal balls, and there is an arc-shaped contact surface between each of the connection pads and the corresponding metal ball. Two build-up circuit structures are respectively formed on the two first insulation protective layers, where the connection pads are electrically connected to the two build-up circuit structures The substrate and the photoresist layer are removed to expose the two first insulation protective layers and the metal balls, where the metal balls and the corresponding connection pads respectively define a plurality of bump structures, and a plurality of top surfaces of the bump structures are on a same plane.

In an embodiment of the invention, the method for manufacturing the package carrier further includes after forming two build-up circuit structures respectively on the two first insulation protective layers and before removing the substrate and the photoresist layer, two second insulation protective layers are respectively formed on the two build-up circuit structures, where the two second insulation protective layers each have a plurality of second openings, and the second openings respectively expose a portion of the two build-up circuit structures.

In an embodiment of the invention, each of the metal balls includes a copper core, a first metal layer, and a second metal layer. The first metal layer covers a surface of the copper core, and the second metal layer covers the first metal layer.

In an embodiment of the invention, the second metal layer completely covers the first metal layer, and the step of removing the substrate and the photoresist layer includes: peeling off the two first copper foil layers and the two second copper foil layers of the substrate to remove the core layer and the two first copper foil layers; removing the two second copper foil layers to expose the photoresist layers and a surface of the second metal layer of each of the metal balls; and removing the photoresist layers to expose the two first insulation protective layers and the metal balls, where the metal balls and the corresponding connection pads respectively define a plurality of flat bump structures.

In an embodiment of the invention, after removing the photoresist layers, a part of the second metal layer of each of the metal balls is removed to expose a part of the first metal layer. The metal balls and the corresponding connection pads respectively define a plurality of top-convex bump structures.

Based on the above, in the design of the package carrier of the invention, the metal balls are respectively disposed in the arc-shaped groove of each of the connection pads, and the metal balls and the corresponding connection pads can define the plurality of bump structures, where the top surfaces of the bump structures are on the same plane. That is, the bump structure of the invention has better coplanarity. In this way, the package carrier of the invention can have better flatness, thereby improving a yield of subsequent chip packaging. In addition, in comparison with a conventional method for forming the copper pillar structure through electroplating and grinding process, in the method for manufacturing the package carrier of the invention, the bump structure is defined through the connection pad and the metal ball. Therefore, there is no need to perform grinding process before the chip packaging, thereby simplifying the manufacturing process and reducing the production costs.

To make the features and advantages of the invention clear and easy to understand, the following gives a detailed description of embodiments with reference to accompanying drawings.

### BRIEF DESCRIPTION OF THE DRAWINGS

FIG. 1A to FIG. 1L are schematic partial cross-sectional views of a method for manufacturing a package carrier according to an embodiment of the invention.

FIG. 2 is a schematic partial cross-sectional view of a package carrier according to an embodiment of the invention.

FIG. 3A is a schematic top view of a package carrier according to another embodiment of the invention.

FIG. 3B is a schematic cross-sectional view taken along a line I-I of FIG. 3A.

### DESCRIPTION OF THE EMBODIMENTS

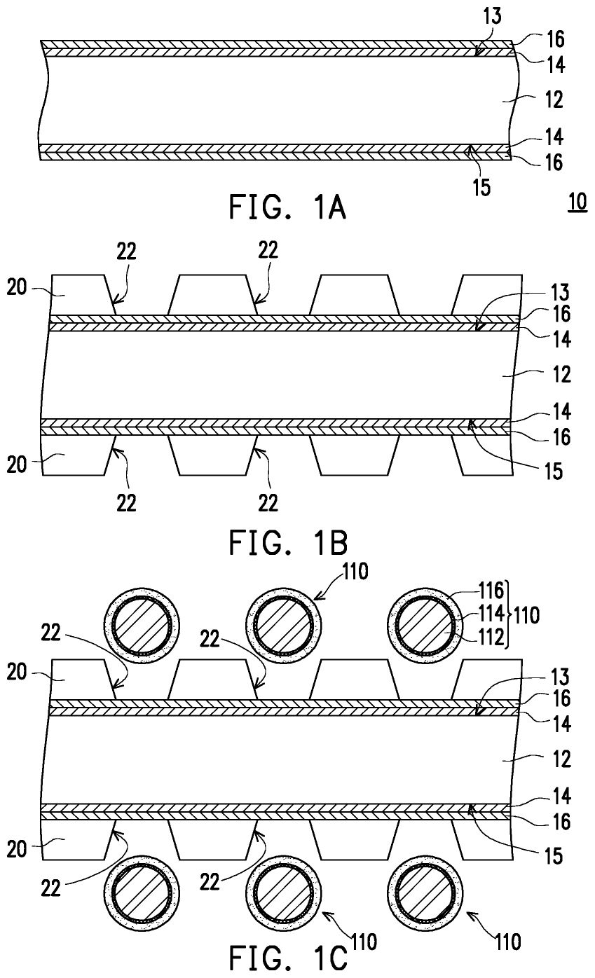

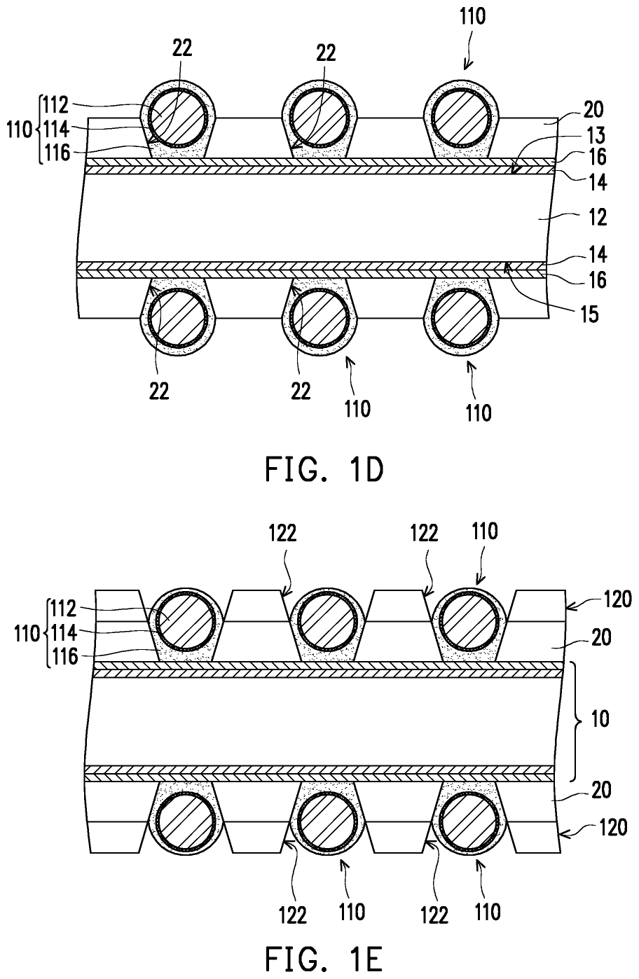

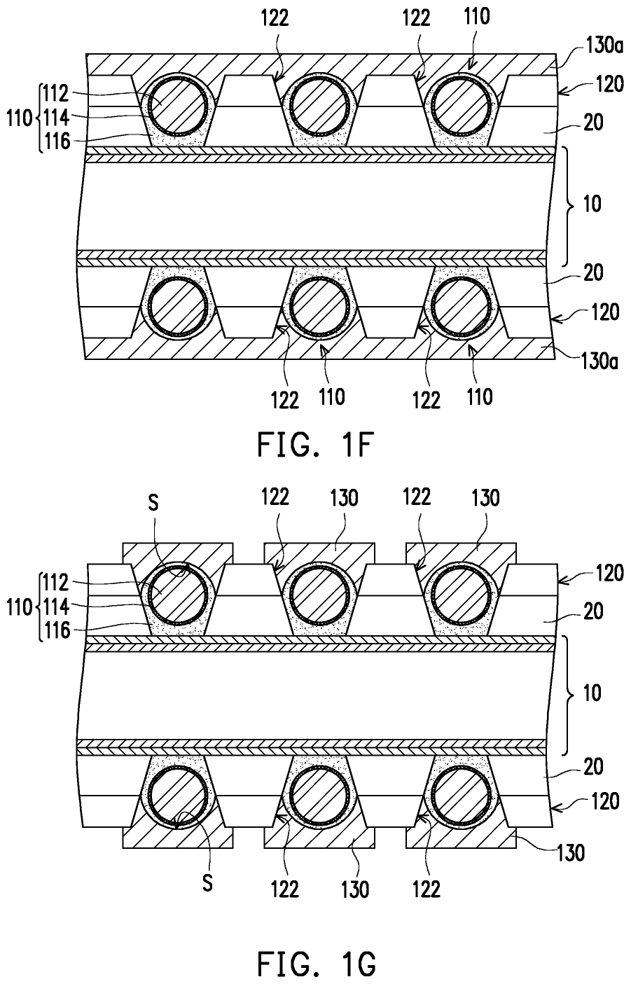

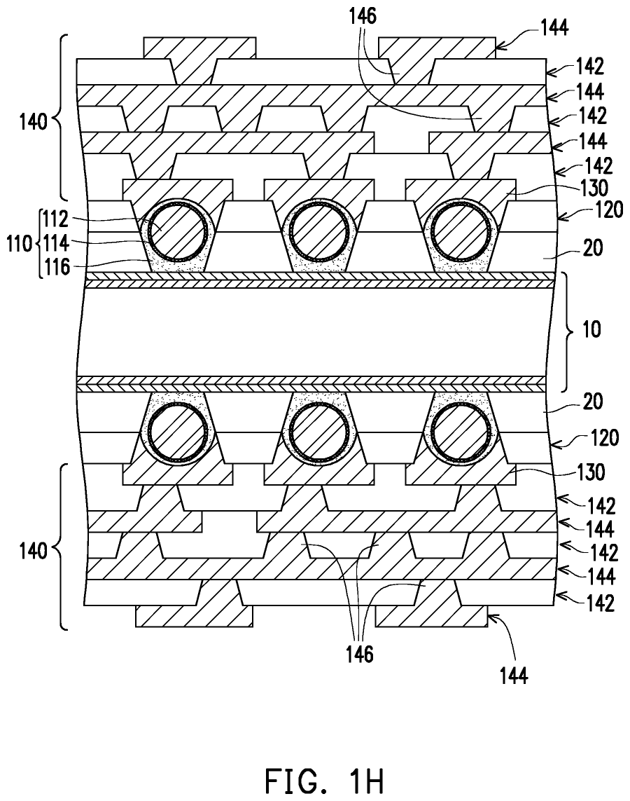

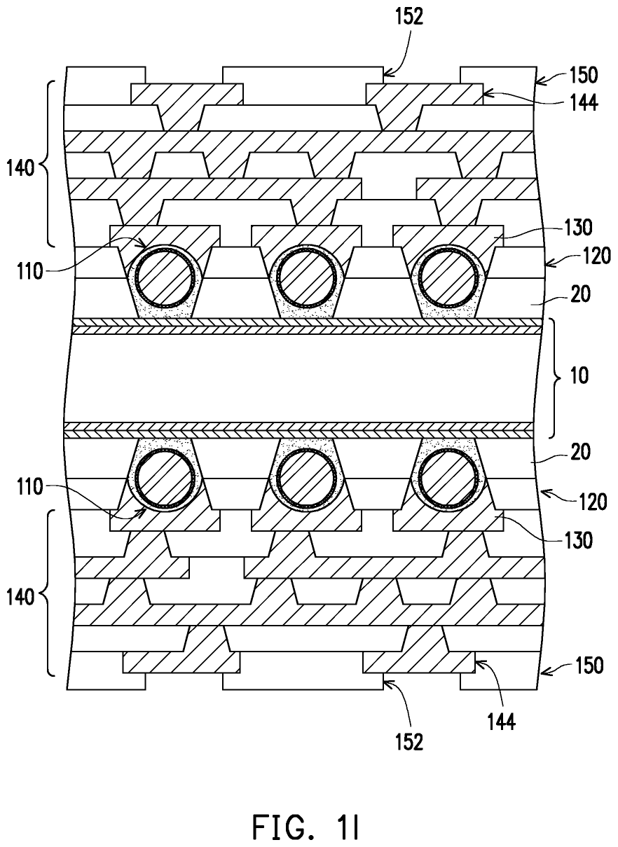

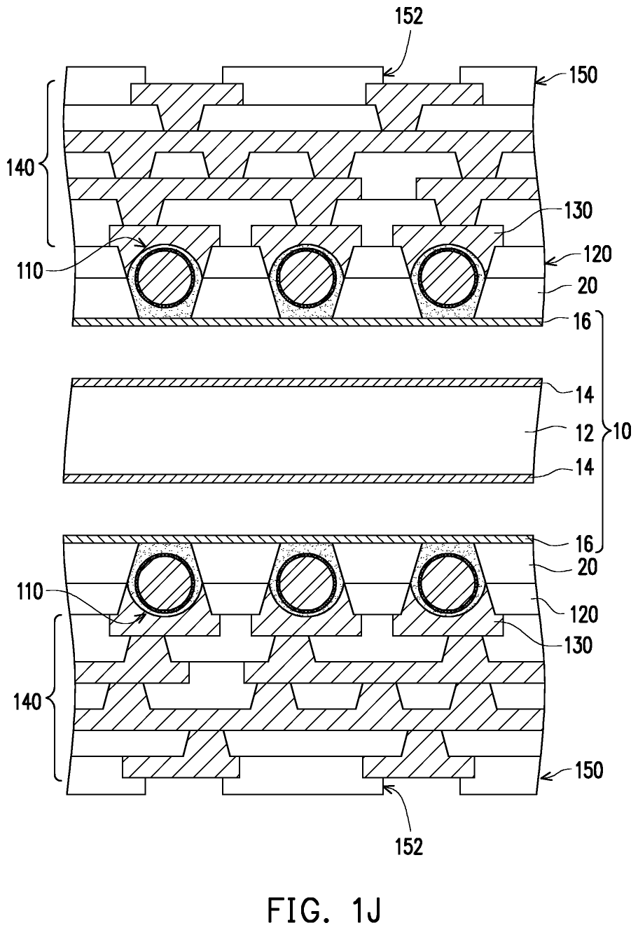

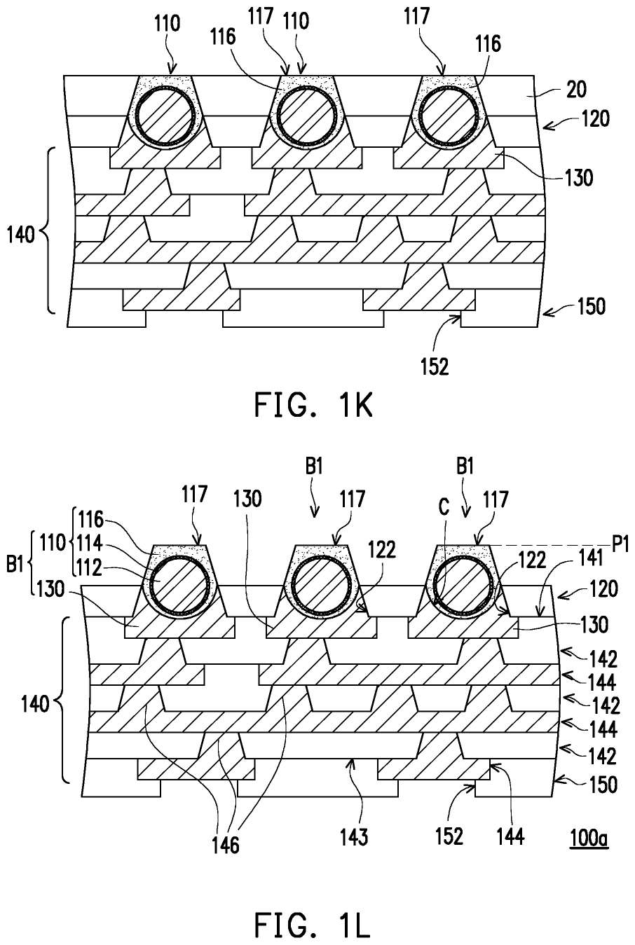

FIG. 1A to FIG. 1L are schematic partial cross-sectional views of a method for manufacturing a package carrier according to an embodiment of the invention. For convenience of description, FIG. 1K and FIG. 1L only show one package carrier on one side after a substrate 10 is removed.

Regarding a method for manufacturing a package carrier in the present embodiment, firstly, referring to FIG. 1A, a substrate 10 is provided. In detail, the substrate 10 in the present embodiment includes a core layer 12, two first copper foil layers 14, and two second copper foil layers 16. The first copper foil layer 14 is disposed on two opposite surfaces 13 and 15 of the core layer 12 and are located between the core layer 12 and the second copper foil layer 16. Herein, the substrate 10 is, for example, a tearable copper foil substrate, and a material of the core layer 12 is, for example, glass fiber, but the invention is not limited to the substrate 10. In other embodiments not shown, the substrate may be a BT resin substrate or other suitable substrates.

Then, referring to FIG. 1B, two photoresist layers 20 are respectively formed on the second copper foil layer 16 of the substrate 10, where the photoresist layers 20 have a plurality of openings 22 respectively, and the openings 22 expose a portion of the second copper foil layer 16. Herein, in the method for forming the photoresist layer 20, a photoresist material layer (not shown) is laminated to the second copper foil layer 16 of the substrate 10 (referring to FIG. 1A) through lamination, and then the photoresist layer 20 having the opening 22 is formed through a laser drill.

Then, first referring to FIG. 1D, a plurality of metal balls 110 are bonded to the second copper foil layers 16 exposed by the openings 22 of the photoresist layer 20. In detail, in the step of bonding the metal balls 110 to the second copper foil layer 16 exposed by the openings 22, firstly, referring to FIG. 1C, the metal balls 110 are provided in the openings 22 of the photoresist layer 20. Each of the metal balls 110 includes a copper core 112, a first metal layer 114, and a second metal layer 116. The first metal layer 114 covers a surface of the copper core 112, and the second metal layer 116 covers the first metal layer 114. Herein, a thickness of the first metal layer 114 is thinner than a thickness of the second metal layer 116, and the first metal layer 114 may be considered as a protective layer to protect the surface of the copper core 112. The first metal layer 114 is, for example, a nickel layer or a gold layer, and the second metal layer 116 is, for example, a pure tin layer, a tin alloy layer, a tin-silver-copper alloy layer, a tin-copper alloy layer, a tin-antimony alloy layer, a tin-lead alloy layer, or the like, but is not limited thereto. Then, referring to FIG. 1D, a reflow process is performed on the metal ball 110 so that the metal balls 110 are bonded through an intermetallic compound, to the second copper foil layer 16 exposed by the openings 22. Still further, after the reflow process, the second metal layer 116 is in a molten state and flows to fill the openings 22 of the photoresist layer 20. In this case, the metal balls 110 are bonded to the second copper foil layer 16 through the molten second metal layer 116.

Then, referring to FIG. 1E, two first insulation protective layers 120 are respectively formed on the two photoresist layers 20, where the first insulation protective layers 120 have a plurality of first openings 122 respectively, and the first openings 122 respectively expose the metal balls 110. Herein, a material of the first insulation protective layers 120 is, for example, a dry film type solder mask, and a model of the dry film type solder mask is, for example, Taiyo AUS SR1, SR3; Hitachi SR7300, SRFA; or Sumitomo LAZ-7751, 7752, but is not limited thereto.

Then, referring to FIG. 1G, a plurality of connection pads 130 are formed in the first openings 122 of the first insulation protective layers 120 and extend onto the first insulation protective layers 120. Herein, the connection pads 130 respectively cover the metal balls 110, and there is an arc-shaped contact surface between each of the connection pads 130 and the corresponding metal ball 110. In detail, in the step of forming the connection pads 130, firstly, referring to FIG. 1F, two copper layers 130a are electroplated on the first insulation protective layers 120, where the copper layer 130a covers the metal balls 110 and fills the first openings 122 and extends onto the first insulation protective layers 120. Because the copper layer 130a covers a surface of the metal balls 110, a connection contact surface between the subsequently formed connection pad 130 and the metal ball 110 is an arc-shaped contact surface S (referring to FIG. 1G). Then, referring to FIG. 1G, two copper layers 130a are patterned, and the connection pads 130 are respectively formed on the metal balls 110. That is, the connection pads 130 are separated from each other and expose a portion of the first insulation protective layers 120.

Then, referring to FIG. 1H, two build-up circuit structures 140 are respectively formed on the first insulation protective layers 120, where the connection pads 130 are structurally and electrically connected to the build-up circuit structures 140. Herein, the build-up circuit structures 140 include at least one dielectric layer 142 (three dielectric layers 142 are schematically showed), at least one circuit layer 144 (three circuit layers 144 are schematically showed), and at least one conductive via 146 (a plurality of conductive vias 146 are schematically showed) respectively. The dielectric layer 142 covers the connection pads 130, the circuit layer 144 is disposed on the dielectric layer 142, and the conductive via 146 penetrates the dielectric layer 142 to electrically connect the connection pads 130 and the circuit layer 144. Herein, the build-up circuit structures 140 are formed through lamination and by electroplating the copper layer. The number of dielectric layers 142 and the number of the circuit layers 144 can be increased or decreased as required, which is not limited herein.

Then, referring to FIG. 1I, two second insulation protective layers 150 are respectively formed on the build-up circuit structures 140, where the second insulation protective layers 150 have a plurality of second openings 152 respectively, and the second openings 152 respectively partially expose the circuit layers 144 of the build-up circuit structures 140. Herein, a material of the second insulation protective layer 150 is, for example, a dry film type solder mask, and a model of the dry film type solder mask is, for example, Taiyo AUS SR1, SR3; Hitachi SR7300, SRFA; or Sumitomo LAZ-7751, 7752, but is not limited thereto.

Finally, referring to FIG. 1J and FIG. 1L, the substrate 10 and the photoresist layer 20 are removed to expose the first insulation protective layers 120 and the metal balls 110. In detail, referring to FIG. 1J, in the step of removing the substrate 10 and the photoresist layers 20, the first copper foil layers 14 and the second copper foil layers 16 of the substrate 10 are firstly peeled off to remove the core layer 12 and the first copper foil layers 14. Then, referring to FIG. 1J and FIG. 1K, the second copper foil layers 16 are removed to expose the photoresist layer 20 and a surface 117 of the second metal layer 116, where the surface 117 of the second metal layer 116 and the photoresist layer 20 are coplanar. Finally, referring to FIG. 1L, the photoresist layer 20 is removed to expose surrounding surfaces of the first insulation protective layer 120 and the second metal layer 116 of the metal balls 110. Herein, the metal balls 110 and the corresponding connection pads 130 may define a plurality of flat bump structures B1. In this case, manufacturing of a package carrier 100a with the flat bump structure B1 and without the core has been completed.

In terms of structure, referring to FIG. 1L again, the package carrier 100a in the present embodiment includes the build-up circuit structure 140, the first insulation protective layer 120, the connection pads 130, and the metal balls 110. The build-up circuit structure 140 has the upper surface 141, and includes the dielectric layer 142, the circuit layer 144, and the conductive via 146. The first insulation protective layer 120 is disposed on the upper surface 141 of the build-up circuit structure 140 and has the first openings 122. The connection pads 130 are respectively disposed in the first openings 122 of the first insulation protective layer 120 and are structurally and electrically connected to the build-up circuit structure 140. Each of the connection pads 130 has an arc-shaped groove C, and the metal balls 110 are respectively disposed in the arc-shaped groove C of each of the connection pads 130. Herein, the dielectric layer 142 covers the connection pads 130, the circuit layer 144 is disposed on the dielectric layer 141, and the conductive via 146 penetrates the dielectric layer 142 to electrically connect the connection pad 130 and the circuit layer 144. Each of the metal balls 110 includes the copper core 112, the first metal layer 114, and the second metal layer 116, where the first metal layer 114 covers a surface of the copper core 112, and the second metal layer 116 covers the first metal layer 114.

Furthermore, the metal balls 110 and the corresponding connection pads 130 in the present embodiment define the flat bump structures B1, where surfaces 117 of the second metal layers 116 of the metal balls 110 are on the same plane P1. In addition, the package carrier 100a in the present embodiment further includes the second insulation protective layer 150 disposed on the lower surface 143 of the build-up circuit structure 140 relative to the upper surface 141 and having the second openings 152, where the second openings 152 expose a portion of the circuit layer 144 of the build-up circuit structure 140.

Since the flat bump structure B1 in the present embodiment includes the metal balls 110 and the corresponding connection pads 130, it means that the copper pillar structure is not formed by electroplating the copper layer, and surfaces 117 of the second metal layers 116 of the metal balls 110 are on the same plane P1. Therefore, the flat bump structure B1 in the present embodiment can have better coplanarity, so that the package carrier 100a in the present embodiment can have better flatness, thereby improving the yield of subsequent chip packaging. In addition, in the present embodiment, better flatness can be achieved without additional grinding process before the chip packaging, thereby simplifying the manufacturing process and reducing the production costs.

It should be noted herein that in the following embodiments, reference numerals and some content of the foregoing embodiments are used, and same reference numerals are used to represent same or similar elements, and descriptions about same technical content are omitted. For the omitted descriptions, reference may be made to the foregoing embodiments, and details are not repeated again in the following embodiments.

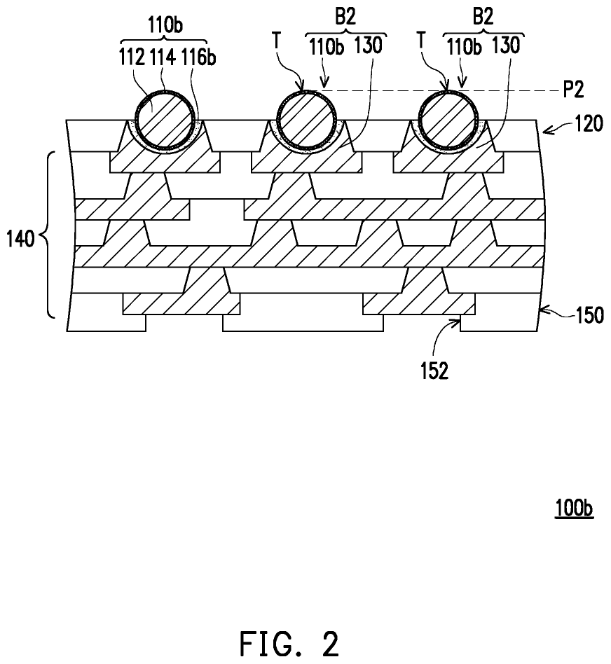

FIG. 2 is a schematic partial cross-sectional view of a package carrier according to an embodiment of the invention. The package carrier 100a in the present embodiment is similar to the above package carrier 100b, and a difference between the two is that after the step of FIG. 1L, that is, after the photoresist layer 20 is removed to expose the first insulation protective layers 120 and the metal balls 110, referring to FIG. 1L and FIG. 2, an etching process is performed to remove a part of the second metal layer 116 of the metal balls 110 and to expose a part of the first metal layer 114 to form the metal balls 110b. Herein, the second metal layer 116b only covers a portion of the first metal layer 114, the second metal layer 116b may be coplanar with the first insulation protective layer 120, and the metal balls 110b including the copper core 112, the first metal layer 114, and the second metal layer 116b and the corresponding connection pad 130 may define a plurality of top-convex bump structures B2, where the top surfaces T of the top-convex bump structures B2 are on the same plane P2. In this case, manufacturing of a package carrier 100b with the top-convex bump structure B2 and without the core has been completed.

In the package carrier 100b in the present embodiment, the metal balls 110b are disposed in the arc-shaped groove C of each of the connection pads 130, and the metal balls 110b and the corresponding connection pads 130 may define the top-convex bump structures B2, where the top surfaces T of the top-convex bump structures B2 are on the same plane P2. That is, the top-convex bump structure B2 in the present embodiment may have better coplanarity. Therefore, the package carrier 100b in the present embodiment can have better flatness, thereby improving the yield of subsequent chip packaging. In addition, in the present embodiment, better flatness can be achieved without grinding process, thereby effectively simplifying the manufacturing process and reducing the production costs.

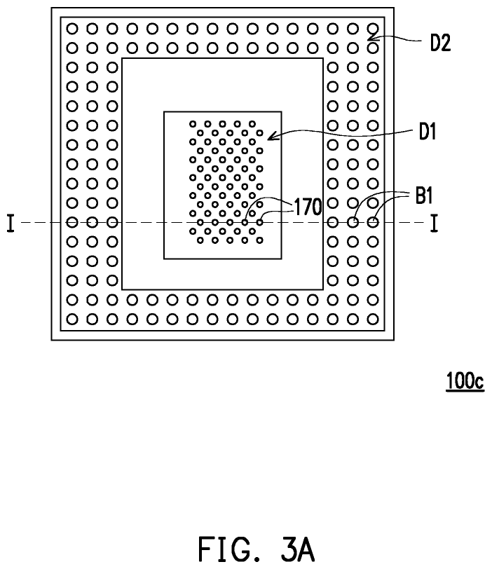

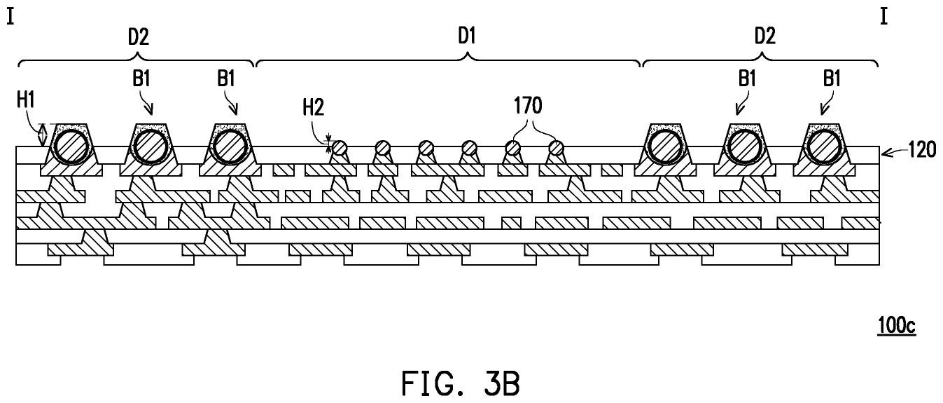

FIG. 3A is a schematic top view of a package carrier according to another embodiment of the invention. FIG. 3B is a schematic cross-sectional view taken along a line I-I of FIG. 3A. Referring to FIG. 3A and FIG. 3B, a package carrier 100c in the present embodiment has a chip disposition area D1 and a peripheral area D2 surrounding the chip disposition area D1. The peripheral area D2 is provided with the flat bump structures B1 shown in FIG. 1L, and the wafer disposition area D1 is provided with the bumps 170. For example, the chip disposition area D1 can be configured with, for example, a chip with a logic calculation processing capability, and the peripheral area D2 can be configured with, for example, a chip with a memory storage function, but it is not limited thereto. The flat bump structure B1 to the first insulation protective layer 120 has a first height H1, and the bump 170 to the first insulation protective layer 120 has a second height H2, where the first height H1 is 3 to 5 times the second height H2.

In view of the above, in the design of the package carrier of the invention, the metal balls are respectively disposed in the arc-shaped groove of each of the connection pads, and the metal balls and the corresponding connection pads can define the plurality of bump structures, where the top surfaces of the bump structures are on the same plane. That is, the bump structure of the invention has better coplanarity. In this way, the package carrier of the invention can have better flatness, thereby improving a yield of subsequent chip packaging. In addition, in comparison with a conventional method for forming the copper pillar structure through electroplating and grinding process, in the method for manufacturing the package carrier of the invention, the bump structure is defined through the connection pad and the metal ball. Therefore, there is no need to perform grinding process before the chip packaging, thereby simplifying the manufacturing process and reducing the production costs.

Although the invention is described with reference to the above embodiments, the embodiments are not intended to limit the invention. A person of ordinary skill in the art may make variations and modifications without departing from the spirit and scope of the invention. Therefore, the protection scope of the invention should be subject to the appended claims.

1. A package carrier, comprising:
a build-up circuit structure having an upper surface;
a first insulation protective layer disposed on the upper surface of the build-up circuit structure and having a plurality of first openings;
a plurality of connection pads respectively disposed in the plurality of first openings of the first insulation protective layer and are structurally and electrically connected to the build-up circuit structure, wherein each of the plurality of connection pads has an arc-shaped groove; and
a plurality of metal balls respectively disposed in the arc-shaped groove of each of the plurality of connection pads, wherein the plurality of metal balls and the corresponding connection pads respectively define a plurality of bump structures, and a plurality of top surfaces of the bump structures are on a same plane.

2. The package carrier according to claim 1, further comprising:
a second insulation protective layer disposed on a lower surface of the build-up circuit structure relative to the upper surface and having a plurality of second openings, wherein the plurality of second openings expose a portion of the build-up circuit structure.

3. The package carrier according to claim 1, wherein the build-up circuit structure comprises at least one dielectric layer, at least one circuit layer, and at least one conductive via, the at least one dielectric layer covers the plurality of connection pads, the at least one circuit layer is disposed on the at least one dielectric layer, and the at least one conductive via penetrates the at least one dielectric layer to electrically connect at least one of the plurality of connection pads and the at least one circuit layer.

4. The package carrier according to claim 1, wherein each of the plurality of metal balls comprises a copper core, a first metal layer, and a second metal layer, the first metal layer covers a surface of the copper core, and the second metal layer covers the first metal layer.

5. The package carrier according to claim 4, wherein the second metal layer completely covers the first metal layer, and the plurality of metal balls and the corresponding connection pads respectively define a plurality of flat bump structures.

6. The package carrier according to claim 4, wherein the second metal layer covers a portion of the first metal layer, and the plurality of metal balls and the corresponding connection pads respectively define a plurality of top-convex bump structures.

7. A method for manufacturing a package carrier, comprising:
providing a substrate comprising a core layer, two first copper foil layers, and two second copper foil layers, wherein the two first copper foil layers are disposed on two opposite surfaces of the core layer and are located between the core layer and the two second copper foil layers;
respectively forming two photoresist layers on the two second copper foil layers of the substrate, wherein the two photoresist layers have a plurality of openings respectively, and the plurality of openings expose a portion of the two second copper foil layers;
bonding a plurality of metal balls to the two second copper foil layers exposed by the plurality of openings;
forming two first insulation protective layers respectively on the two photoresist layers, wherein the two first insulation protective layers have a plurality of first openings respectively, and the plurality of first openings respectively expose the plurality of metal balls;
forming a plurality of connection pads in the plurality of first openings of the two first insulation protective layers and extending onto the two first insulation protective layers, wherein the plurality of connection pads respectively cover the plurality of metal balls, and there is an arc-shaped contact surface between each of the plurality of connection pads and the corresponding metal ball;
forming two build-up circuit structures respectively on the two first insulation protective layers, wherein the plurality of connection pads are electrically connected to the two build-up circuit structures; and
removing the substrate and the photoresist layer to expose the two first insulation protective layers and the plurality of metal balls, wherein the plurality of metal balls and the corresponding connection pads respectively define a plurality of bump structures, and a plurality of top surfaces of the bump structures are on a same plane.

8. The method for manufacturing the package carrier according to claim 7, further comprising:
after forming the two build-up circuit structures respectively on the two first insulation protective layers and before removing the substrate and the photoresist layer, forming two second insulation protective layers respectively on the two build-up circuit structures, wherein the two second insulation protective layers respectively have a plurality of second openings, and the plurality of second openings respectively expose a portion of the two build-up circuit structures.

9. The method for manufacturing the package carrier according to claim 7, wherein each of the plurality of metal balls comprises a copper core, a first metal layer, and a second metal layer, the first metal layer covers a surface of the copper core, and the second metal layer covers the first metal layer.

10. The method for manufacturing the package carrier according to claim 9, wherein the second metal layer completely covers the first metal layer, and the step of removing the substrate and the photoresist layer comprises:
peeling off the two first copper foil layers and the two second copper foil layers of the substrate to remove the core layer and the two first copper foil layers;
removing the two second copper foil layers to expose the photoresist layers and a surface of the second metal layer of each of the plurality of metal balls; and
removing the photoresist layers to expose the two first insulation protective layers and the plurality of metal balls, wherein the plurality of metal balls and the corresponding connection pads respectively define a plurality of flat bump structures.

11. The method for manufacturing the package carrier according to claim 10, wherein after removing the photoresist layers, a part of the second metal layer of each of the plurality of metal balls is removed to expose a part of the first metal layer, and the plurality of metal balls and the corresponding connection pads respectively define a plurality of top-convex bump structures.
